(19) United States
(12) Patent Application Publication
(10) Pub. No.: US 2026/0333787 A1
(43) Pub. Date: Oct. 22, 2026

(54) RESURF AND MULTI-GATE TECHNIQUES FOR LDMOS DEVICES

(71) Applicant: Renesas Electronics America Inc., Milpitas, CA (US)

(72) Inventors: Gourab SABUI, Milpitas, CA (US); Marco ZUNIGA, Milpitas, CA (US)

(73) Assignee: Renesas Electronics America Inc., Milpitas, CA (US)

(21) Appl. No.: 19/389,624

(22) Filed: Nov. 14, 2025

Related U.S. Application Data
(60) Provisional application No. 63/790,930, filed on Apr. 18, 2025.

(51) Int. Cl. H10D 62/10; H10D 30/60; H10D 30/65; H10D 64/27

(52) U.S. Cl. CPC H10D 62/109; H10D 30/611; H10D 30/65; H10D 64/516; H10D 64/518

(57) ABSTRACT

A semiconductor device includes a gate electrode positioned on a semiconductor substrate via a gate insulating film. A drift layer of a first conductivity type is located on the semiconductor substrate and extends from one end of the gate electrode in a gate length direction. A drain region of the first conductivity type is positioned at an extended end of the drift layer. A P-type body region of a second conductivity type is located on the semiconductor substrate on another end of the gate electrode in the gate length direction. A source region of the first conductivity type is located in the P-type body region. A reduced surface field (RESURF) region of the second conductivity type is in contact with a bottom of the drift layer and the P-type body region. Below the drain region, the RESURF region includes extension regions and a protruded portion extending into the drain region.

### CROSS-REFERENCE TO RELATED APPLICATION

This application claims the benefit of priority under 35 U.S.C. §119(e) to U.S. Provisional Application No. 63/790,930, filed on Apr. 18, 2025, titled “RESURF AND MULTI-GATE TECHNIQUES FOR LDMOS DEVICES,” the entire disclosure of which is incorporated by reference herein.

### BACKGROUND

The present disclosure generally relates to the field of semiconductor device fabrication, and more particularly to fabrication of laterally diffused metal-oxide-semiconductor (LDMOS) devices.

LDMOS transistors are a type of power metal-oxide-semiconductor field-effect transistor (MOSFET) widely used in RF amplifiers, wireless infrastructure, and high-voltage switching applications. Their popularity stems from their ability to handle high voltages and deliver high output power with excellent linearity, making them particularly suitable for base stations, industrial power supplies, and automotive electronics. LDMOS devices typically feature a laterally extended drift region, allowing for efficient distribution of the electric field across the device and enabling high breakdown voltage performance while maintaining compact layout geometries. This lateral structure also facilitates integration in standard CMOS-compatible processes, reducing manufacturing complexity and cost.

To further enhance voltage tolerance and device efficiency, conventional LDMOS structures often employ a reduced surface field (RESURF) technique. This involves alternating N-type and P-type layers (e.g., N-RESURF and P-RESURF) within the drift region to spread the electric field uniformly and suppress premature breakdown, thereby allowing for high-voltage operation without significantly increasing the chip area. Despite these advantages, LDMOS devices face several design challenges, including trade-offs between breakdown voltage and on-resistance, and sensitivity to hot-carrier effects and self-heating under high-power operation. Optimizing the device structure to improve ruggedness and reliability while maintaining performance remains an active area of development.

### SUMMARY

According to an embodiment of the present disclosure, a semiconductor device includes a gate electrode positioned on a semiconductor substrate via a gate insulating film, a drift layer of a first conductivity type located on the semiconductor substrate and extending from one end side of the gate electrode in a gate length direction, a drain region of the first conductivity type positioned at an extended end of the drift layer, a P-type body region of a second conductivity type opposite to the first conductivity type positioned on the semiconductor substrate on another end side of the gate electrode in the gate length direction, a source region of the first conductivity type positioned on the semiconductor substrate on the P-type body region, and a reduced surface field (RESURF) region of the second conductivity type in contact with a bottom of the drift layer and the P-type body region, below the drain region, the reduced surface field region has a plurality of extension regions with a protruded portion extending into the drain region.

According to another embodiment of the present disclosure, a semiconductor device includes a drift layer of a first conductivity type disposed on a semiconductor substrate, a first gate electrode positioned on the drift layer via a first gate insulating film, a second gate electrode positioned adjacent to the first gate electrode on the drift layer via a second gate insulating film, a drain region of the first conductivity type disposed in the drift layer on a side of the second gate electrode opposite the first gate electrode, a P-type body region of a second conductivity type, opposite to the first conductivity type, positioned in the drift layer on a side of the first gate electrode opposite the second gate electrode, a source region of the first conductivity type positioned in the P-type body region, and a third gate electrode positioned on the drift layer adjacent to the P-type body region via a third gate insulating film, a first current path extending from the source region to the drain region through the drift layer along a surface of the P-type body region, a second current path extending from the source region to the drain region through the drift layer by detouring below a region of the drift layer beneath the P-type body region, the first gate electrode and the second gate electrode control a current flow through the first current path, the third gate electrode controls a current flow through the second current path, and the first gate electrode and the second gate electrode are activated after the third gate electrode is activated.

### BRIEF DESCRIPTION OF THE DRAWINGS

The following detailed description, given by way of example and not intended to limit the embodiments described herein, will best be appreciated in conjunction with the accompanying drawings, in which:

FIG. 1A is a cross-sectional view of a semiconductor device taken along a section line A-A’ depicted in FIG. 1C, according to an embodiment of the present disclosure;

FIG. 1B is a cross-sectional view of the semiconductor device taken along a section line B-B’ depicted in FIG. 1C, according to an embodiment of the present disclosure;

FIG. 1C is a schematic top-down view of the semiconductor device showing an arrangement of a plurality of extension regions, according to an embodiment of the present disclosure;

FIG. 2A is a cross-sectional view of another semiconductor device illustrating a dual-gate configuration with an alternative gate switching scheme, according to an embodiment of the present disclosure;

FIG. 2B is a cross-sectional view of the semiconductor device illustrating an example of dual-gate configuration with alternative gate switching scheme in which a RESURF region is provided in an upper portion of a drift layer, according to an embodiment of the present disclosure;

FIG. 3A is a cross-sectional view the semiconductor device illustrating a dual-gate structure with RESURF region extending laterally across the semiconductor device, according to an embodiment of the present disclosure;

FIG. 3B is a cross-sectional view of the semiconductor device illustrating an example of dual-gate configuration of FIG. 3A in which the RESURF region does not extend laterally across the semiconductor device, according to an embodiment of the present disclosure;

FIG. 4A is a cross-sectional view of the semiconductor device illustrating a dual-gate structure in which the RESURF region is laterally continuous across a width of the semiconductor device and includes a plurality of extension regions below the drain region, according to an embodiment of the present disclosure;

FIG. 4B is a cross-sectional view of the semiconductor device illustrating an example of the dual-gate structure of FIG. 4A in which the RESURF region partially extends across the device width, according to an embodiment of the present disclosure;

FIG. 5 is a cross-sectional view of the semiconductor device illustrating a dual-gate configuration in which a gate electrode is implemented as a trench gate, according to an embodiment of the present disclosure; and

FIG. 6 is a cross-sectional view of the semiconductor device illustrating a dual-gate configuration including two distinct P-body regions, according to an embodiment of the present disclosure.

The drawings are not necessarily to scale. The drawings are merely schematic representations, not intended to portray specific parameters of the embodiments in the present disclosure. The drawings are intended to depict typical embodiments of the present disclosure. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. The claimed structures and methods may, however, be embodied in many different forms and should not be construed as limited to the exemplary embodiments set forth herein. In the description, details of various conventional features and techniques may be omitted to avoid unnecessarily obscuring the presented embodiments.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present disclosure, in the following detailed description, some processing steps or operations that may be ordinary in the art may have been combined together for presentation and for illustration purposes and in some instances may have not been described in detail. In other instances, some processing steps or operations that may be ordinary in the art may not be described at all. It should be understood that the following description is rather focused on the distinctive features or elements of various embodiments of the present disclosure.

Embodiments of the present disclosure provide alternative RESURF and multi-gate techniques for LDMOS devices, including dual-gate configurations with independent gate control, staggered and interleaved RESURF and extension regions, trench-based auxiliary gates for finer pitch and improved current spreading, and dual P-body structures optimized for different gate oxide voltages to reduce switching losses.

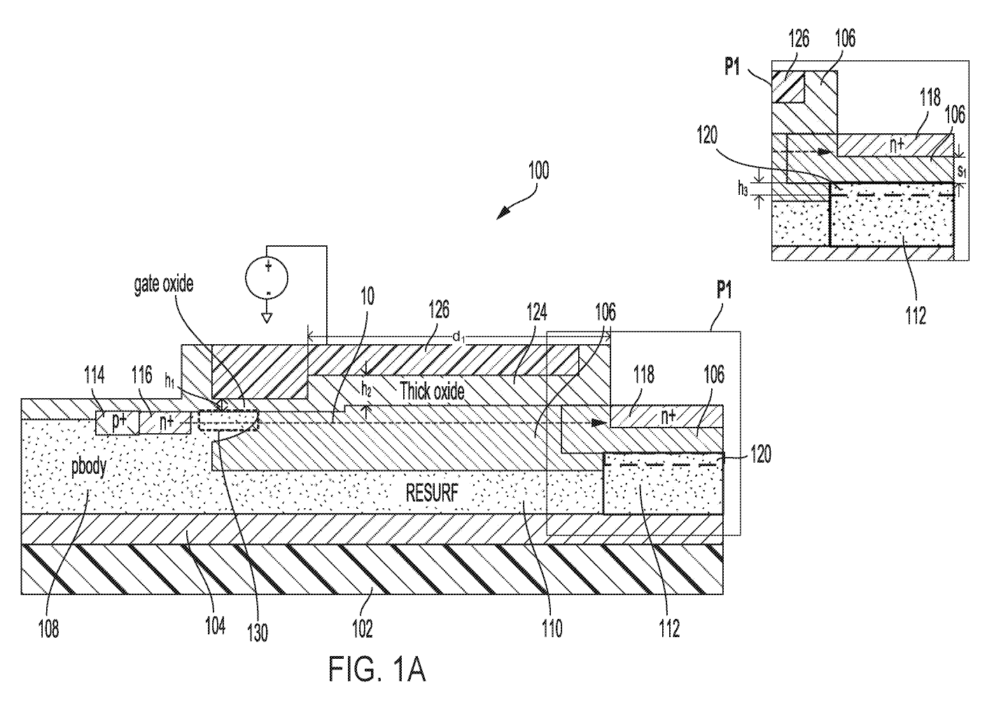

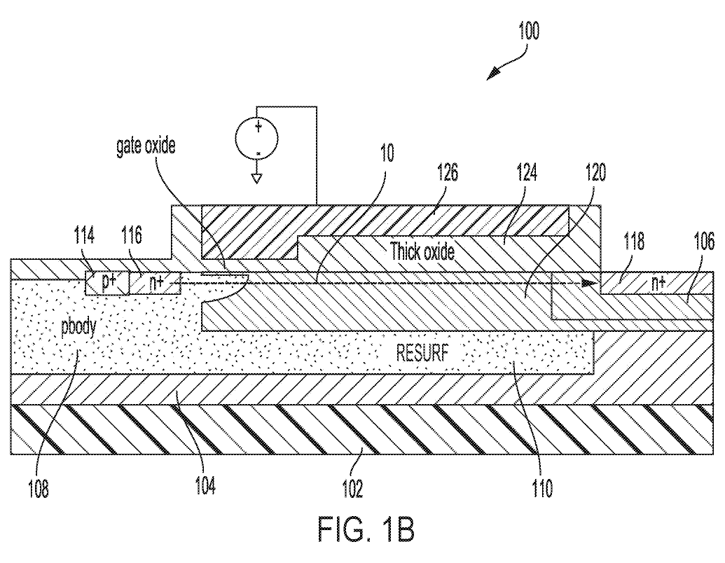

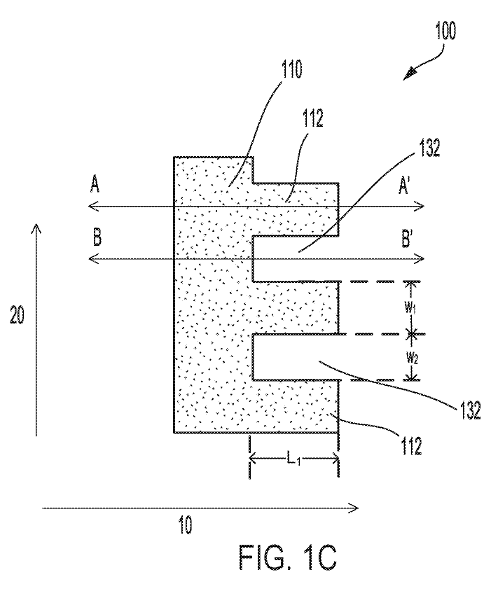

Embodiments by which RESURF and multi-gate techniques can be implemented in LDMOS devices are described in detail below by referring to FIGS. 1A-6.

Referring now to FIGS. 1A-1C, FIG. 1A is a cross-sectional view of a semiconductor device 100 taken along a section line A-A’ depicted in FIG. 1C, according to an embodiment of the present disclosure. FIG. 1B is a cross-sectional view of the semiconductor device 100 taken along a section line B-B’ depicted in FIG. 1C. As illustrated in FIG. 1C, the section line A-A’ passes through one of a plurality of extension regions (hereinafter “extension regions”) 112 of a reduced surface field (RESURF) region 110, while the section line B-B’ passes between adjacent extension regions 112 of the RESURF region 110. FIG. 1C is a schematic top-down view of the semiconductor device 100 showing an arrangement of the extension regions 112 of the RESURF region 110 located beneath a drain region 118, according to an embodiment of the present disclosure.

The semiconductor device 100 is formed on a semiconductor substrate (hereinafter “substrate”) 102. A drift layer 106 of a first conductivity type (e.g., N-type) is disposed on the substrate 102. The substrate 102 may be of a second conductivity type (e.g., P-type). The drift layer 106 may be formed, for example, as an epitaxial layer of the first conductivity type on the substrate 102. Another way of forming the drift layer 106 is to implant an n-type dopant (e.g., phosphorus) and perform a thermal drive-in, either directly on the substrate or on a previously grown epitaxial layer. A well region 104 may optionally be provided between the substrate 102 and the drift layer 106 to provide device isolation and support the device structure.

A P-type body region (hereinafter “body region”) 108 of the second conductivity type (e.g., P-type) is formed in the drift layer 106 by, for example, patterned ion implantation and thermal drive-in. The body region 108 is formed adjacent to a first side of a gate electrode 126 in a gate length direction 10 (i.e., source-drain direction) indicated by the arrow. A source region 116 of the first conductivity type is formed within the body region 108. A contact region 114 of the second conductivity type may be included in the body region 108 to improve body contact.

On a second side of the gate electrode 126, opposite to the first side of the gate electrode 126 in the gate length direction 10, a drain region 118 of the first conductivity type is formed at an extended end of the drift layer 106. Between the source region 116 and the drain region 118, the gate electrode 126 is disposed on the drift layer 106 via a gate insulating film 124. The gate insulating film 124 includes a first (thin) film portion (e.g., a 1.2 V, 1.8 V, 3.3 V, or 5 V gate oxide) near a channel region 130 and a second (thick) film portion extending from the channel region 130 toward the drain region 118 along the drift layer 106 to reduce electric-field crowding. A thickness h1 of the first film portion of the gate insulating film 124 may be of approximately 1nm to approximately 100nm, while a thickness h2 of the second film portion of the gate insulating film 124 may be of approximately 1nm to approximately 5000 nm. The thick film portion of the gate insulating film 124 may extend a distance d1 of approximately 0.4 μm to approximately 20 μm toward the drain region 118.

The RESURF region 110 of the second conductivity type is formed in contact with a bottom surface of the drift layer 106, as depicted in FIGS. 1A-1B, and extends laterally to contact the body region 108. The RESURF region 110 may be formed, for example, by implanting dopants of the second conductivity type into a region contacting the bottom of the drift layer 106 and then performing a drive-in/anneal, or by selectively forming an epitaxial region of the second conductivity type, so as to laterally contact the body region 108. Below the drain region 118, the RESURF region 110 includes an extension region 112 which has a protruded portion 120 that extends upward from a main portion of the RESURF region 110 toward the drain region 118. FIG. 1A further includes an enlarged detail view of a representative area P1 of the semiconductor device 100 containing the extension region 112 and its corresponding protruded portion 120. As described above, the cross-section of FIG. 1A corresponds to the section line A-A’ passing through one of the extension regions 112, as depicted in FIG. 1C, so the protruded portion 120 is visible in profile.

The protruded portion(s) 120 may extend to a height h₃ of approximately 200 nm to approximately 500 nm from the bottom of the drift layer 106, with a spacing s₁ from a top of (each) protruded portion 120 to a bottom of the drain region 118 varying between approximately 200 nm to approximately 1000 nm. The drift layer 106 may extend laterally between a side or sidewall of (each) protruded portion 120 and the drain region 118 to provide lateral current spreading and control breakdown behavior.

In the configuration of FIG. 1A, the protruded portions 120 are positioned directly beneath the drain region 118 providing an aligned configuration. This geometry facilitates controlled avalanche at a defined voltage while maintaining robustness to repetitive avalanche events, and the RESURF arrangement helps reduce avalanche resistance.

In the configuration of FIG. 1B, the RESURF region 110 beneath the drain region 118 does not include a protruded portion 120, because the cut is taken through an area between the extension regions 112, as depicted in FIG. 1C. Thus, FIG. 1B illustrates a complementary structure compared to FIG. 1A, i.e., instead of intersecting an extension region 112, the cut intersects a gap area in which no extension region is present. The general arrangement of the substrate 102, drift layer 106, well region 104, body region 108, source region 116, contact region 114, drain region 118, gate electrode 126, and gate insulating film 124 in FIG. 1B is the same as in FIG. 1A.

As shown in the top-down view of FIG. 1C, the extension regions 112 are arranged in a comb-like pattern, i.e., elongated regions (the “teeth” of the comb) alternating with intervening spaces 132 in which no extension regions 112 are formed. The extension regions 112 and the intervening spaces 132 are repeated along a gate width direction 20, which is orthogonal to the gate length direction 10.

A width W₁ of areas of the RESURF region 110 containing the extension regions 112 in the gate width direction 20 may be approximately 0.2 μm to approximately 5 μm, and a width W₂ of areas of the RESURF region 110 (i.e., intervening spaces 132) without extension regions 112 in the gate width direction 20 may be approximately 0.2 μm to approximately 5 μm. An extension length L₁ of areas of the RESURF region 110 containing the extension regions 112 in the gate length direction 10 may vary between approximately 0.2 μm to approximately 2 μm.

In some embodiments, the alternating comb-like arrangement shown in FIG. 1C distributes avalanche current laterally across multiple extension regions and gaps to reduce parasitic capacitances while preserving avalanche ruggedness.

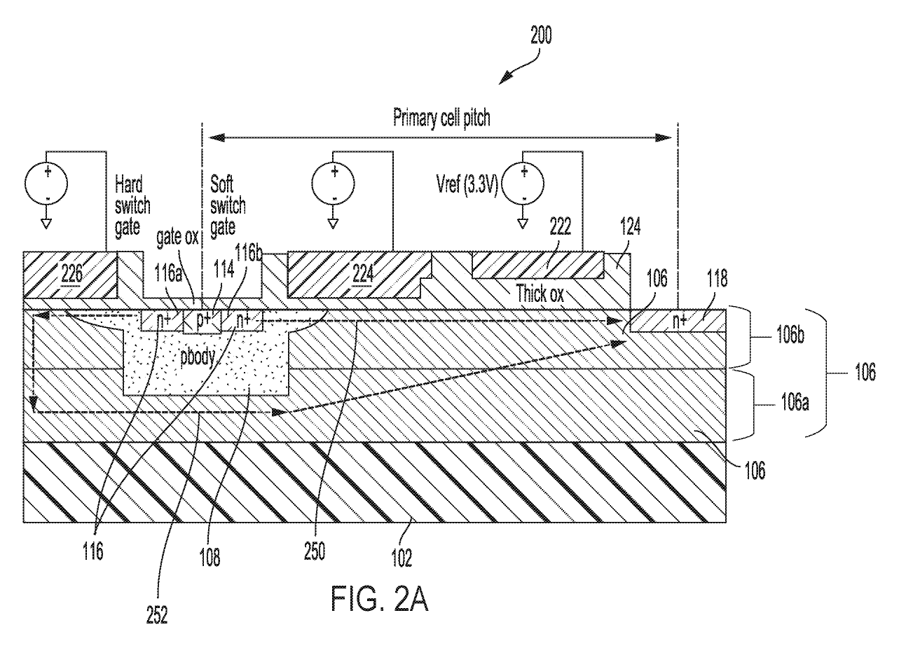

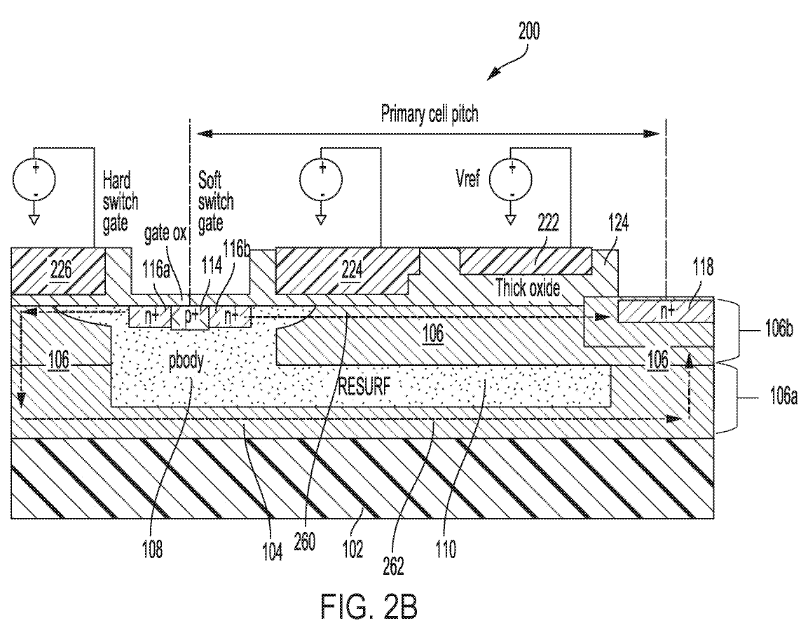

Referring now to FIGS. 2A-2B, cross-sectional views of a semiconductor device 200 illustrating a multi-gate structure with an alternative gate switching scheme are shown, according to an embodiment of the present disclosure. FIG. 2A illustrates a dual-gate configuration with RESURF region 110 providing at least two conduction paths. FIG. 2B illustrates an example of the dual-gate configuration of FIG. 2A in which the RESURF region 110 is provided in an upper portion of the drift layer 106.

For ease of description, elements that are identical or functionally analogous to those previously described with reference to FIGS. 1A-1C are denoted by the same reference numerals in FIGS. 2A-2B. Unless otherwise noted, such elements have substantially the same structure and operation as previously described, and repeated description is omitted.

In this embodiment, the drift layer 106 is a laminate structure including a first drift layer 106a and a second drift layer 106b laminated in that order from the substrate 102 upward.

A first gate electrode 224, a second gate electrode 222, and a third gate electrode 226 are disposed on the upper portion of the drift layer 106, i.e., the second drift layer 106b. The first gate electrode 224 is disposed between the second gate electrode 222 and the third gate electrode 226 separated by corresponding portions of the gate insulating film 124. In this embodiment, the body region 108 (pbody) is positioned in the drift layer 106 between the first gate electrode 224 and the third gate electrode 226. Specifically, the body region 108 is formed on one side of the first gate electrode 224 in a gate length direction (source-drain direction). Within the body region 108, two n⁺ source diffusions 116a and 116b may be formed on opposite sides of the contact region 114. The n⁺ source diffusions 116a, 116b are electrically common and together constitute the source region 116 of the semiconductor device 100. The (p+) contact region 114 provides the body connection, which may be tied to the (n+) source region 116 or kept separately contactable (e.g., for body-biasing). The drain region 118 of the first conductivity type is disposed at an extended end of the second drift layer 106b on a side opposite the body region 108.

Similar to FIGS. 1A-1C, a portion of the gate insulating film 124 located beneath the second (auxiliary) gate electrode 222 may be substantially thicker than portions of the gate insulating film 124 located beneath the first gate electrode 224 and the third gate electrode 226, as depicted in FIGS. 2A-2B.

In the depicted example, each primary cell of the semiconductor device 200 includes two gate electrodes: the third gate electrode 226 which can be a hard switch gate and the first gate electrode 224 which can be a soft switch gate. The first gate electrode 224 and the third gate electrode 226 may be controlled independently to shape the switching behavior. The soft and hard gate segments are biased using a common reference gate voltage (e.g., 1.2V, 3.3V, 5 V), but may be driven with different timing or control logic. The depicted switching scheme may enable improved control over current flow and electric field distribution, which can enhance device performance and reliability during high-voltage operation.

In traditional configurations, a single gate electrode controls a primary or first conduction channel 250 from the source region 116 to the drain region 118 across a top surface of the semiconductor device 200 (i.e., second drift layer 160b). In the proposed dual-gate structure, however, a second conduction channel 252 is formed underneath the body region 108, allowing current to flow laterally from the source region 116, beneath the body region 108, and then rise again toward the drain region 118, as depicted in FIG. 2A. This results in two vertically separated conduction channels (i.e., the first conduction channel 250 and second conduction channel 252). The first conduction channel 250 is formed near a surface of the semiconductor device 200 and the second conduction channel 252 is formed below an upper surface of the semiconductor device 200. The proposed gate switching scheme may enable independent or coordinated control of the first and second conduction channels 250, 252, offering flexibility in switching behavior and improved device performance under various load conditions.

In the configuration shown in FIGS. 2A-2B, the soft-switch gate or first gate electrode 224 located to the right of the source region 116 may resemble a traditional control gate segment for the first conduction channel 250 formed on the surface of the semiconductor device 200, while the hard-switch gate or third gate electrode 226 can be timed to manage hard-switching events. By sequencing the first and third gate electrodes 224, 226 so that one gate segment turns on earlier (e.g., to establish or assist the second conduction channel 252 under the body region 108) and the other segment follows (e.g., to enhance the first conduction channel 250), switching stress can be partitioned: the earlier-activated segment mitigates hard-switch transients, and the later-activated segment can be optimized for low on-resistance. Because the second conduction channel 252 is located under the body region 108 relative to the drain region 118, it is shielded from the high voltage of the drain region 118. As a result, hard switching transients can be more benign due to the absence of a high electric field (e-field) in that region.

Stated differently, two distinct current paths are established from the source region 116 to the drain region 118. A first current path (surface path or first conduction channel 250) flows laterally in the drift layer 106 along the surface of the body region 108. The second gate electrode 222 and the first gate electrode 224 cooperate to control this current. A second current path (detoured path or second conduction channel 252) drops below the RESURF region 110 within the drift layer 106 while remaining adjacent to the body region 108, for example, descending into the first drift layer 106a beneath the body region 108, continuing laterally, and then rising toward the drain region 118. The third gate electrode 226 controls this detoured current. In FIG. 2A, the dashed trajectory schematically indicates the detoured path (second conduction channel 252) that travels below the body region 108 before returning toward the surface near the drain region 118.

In operation, a driver may activate the third gate electrode 226 before activating the first and second gate electrodes 224, 222, thereby pre-establishing a benign electric field detoured path to absorb hard-switching stress. After the third gate electrode 226 is turned ON, the first and second gate electrodes 224, 222 can be activated to establish the main surface conduction (first conduction channel 250). In some embodiments, the first and second gate electrodes 224, 222 are activated simultaneously. Deactivation may proceed in the reverse order (first/second gate electrode 224, 222, then third gate electrode 226) to manage switching stress.

In embodiments in which the drift layer 106 is laminated, the body region 108 may be positioned on the second drift layer 106b and partially expand into the first drift layer 106a. In this arrangement, the first drift layer 106a is electrically connected to the drain region 118 through the second drift layer 106b, and is electrically connected to the source region 116 through the second drift layer 106b and the body region 108. For instance, a first MOSFET formed by the first gate electrode 224 and a corresponding (first) portion of the gate insulating film 124 together with the second gate electrode 222 and a corresponding (second) portion of the gate insulating film 124 may control the first current (e.g., first conduction channel 250) flowing through the second drift layer 106b between the source region 116 and drain region 118, while a second MOSFET formed by the third gate electrode 226 and a corresponding (third) portion of the gate insulating film 124 may control a second current (e.g., second conduction channel 252) detoured below the body region 108 through the first drift layer 106a.

FIG. 2B depicts the semiconductor device 200 including the RESURF region 110 of the second conductivity type positioned in an upper portion of the first drift layer 106a and extending from the body region 108 toward a region below the first gate electrode 224 and the second gate electrode 222. In this configuration, conduction from source region 116 to drain region 118 can be viewed as including two components: a first current 260 flowing through the second drift layer 106b (surface-proximate path) controlled by the first and second MOSFETs described above, and a second current 262 flowing below the RESURF region 110 through the first drift layer 106a, controlled by the third gate electrode 226. Gate timing may again be selected so that the third gate electrode 226 is activated prior to the first and second gate electrodes 224, 222, with the first and second gate electrodes 224, 222 optionally activated simultaneously. It should be noted that the first and second currents 260, 262 represent segments of the same conduction stream. Carriers can proceed laterally from the source region 116 to the drain region 118 (first path or current 260), and also descend below the RESURF region 110 into the first drift layer 106a, continue laterally toward the drain, and finally rise to reach the drain region 118.

The multi-gate cell structure of FIGS. 2A-2B therefore provides (i) a surface path that runs along the surface of the body region 108 and is governed by the first and second gate electrodes 224, 222, and (ii) a deep detoured path that drops below the RESURF region 110 within the drift layer 106 while remaining adjacent to the body region 108 and is governed by the third gate electrode 226. This arrangement allows independent or coordinated control over conduction and switching stress, enabling improved performance and ruggedness at high voltage. For clarity, layer thicknesses and dopant profiles are not to scale and may be simplified in the drawings.

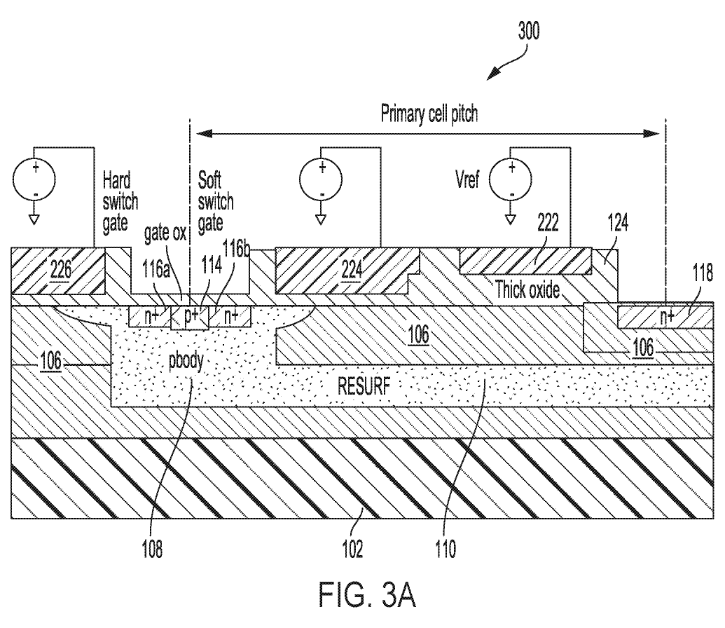

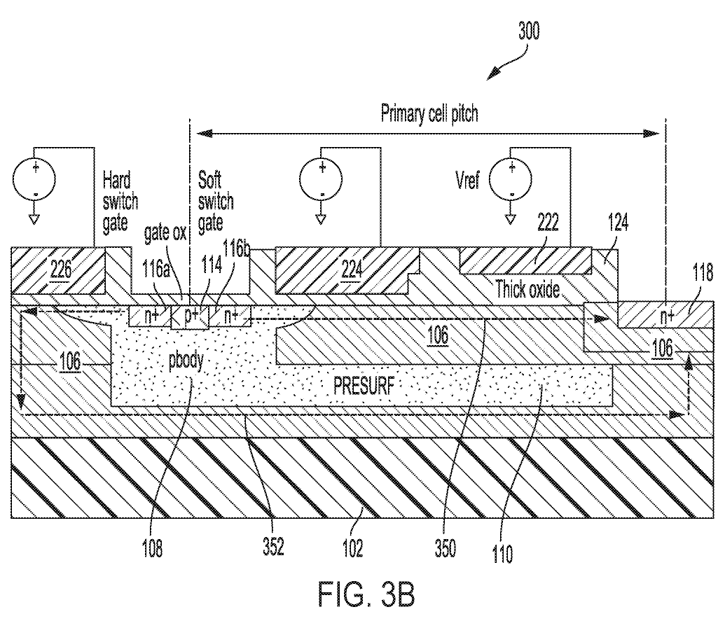

Referring now to FIGS. 3A-3B, cross-sectional views of a semiconductor device 300 illustrating an alternate multi-gate structure are shown, according to an embodiment of the present disclosure. FIG. 3A illustrates an alternate dual-gate configuration in which RESURF region 110 extends laterally across a width of the semiconductor device 300. FIG. 3B illustrates a complementary cross-section of the dual-gate configuration of FIG. 3A taken along a gate-width (z) direction through a gap of the RESURF region 110 (i.e., the RESURF region 110 does not extend laterally across the semiconductor device 300).

For ease of description, elements that are identical or functionally analogous to those previously described with reference to FIGS. 1A-2B are denoted by the same reference numerals in FIGS. 3A-3B. Unless otherwise noted, such elements have substantially the same structure and operation as previously described, and repeated description is omitted.

In the illustrated implementation, each cell includes two surface gates, i.e., the first gate electrode 224 (soft-switch gate) and the third gate electrode 226 (hard-switch gate) that may be biased from a common reference (e.g., Vref ≈ 3.3 V) but driven with different timing or control logic (see primary cell pitch).

As shown in FIG. 3A, the RESURF region 110 is positioned in the drift layer 106 and extends from the body region 108 beneath the first gate electrode 224 and the second gate electrode 222, and further extends beneath the drain region 118, thereby shaping the surface electric field under surface-path gates and near the drain region 118. The first gate electrode 224 and the third gate electrode 226 are positioned on the drift layer 106 via corresponding portions of the gate insulating film 124. Similar to FIGS. 2A-2B, source region 116 (with contact region 114) is formed in the body region 108, and the drain region 118 of the first conductivity type is located in the drift layer 106 on a side of the second gate electrode 222 opposite the first gate electrode 224.

In the arrangement of FIG. 3A, the RESURF region 110 laterally spans the semiconductor device 300 to implement controlled avalanche clamping near the drain region 118. However, fully extending the RESURF region 110 can block the formation of a secondary conduction channel, as the P-type material impedes current flow. To address this, openings or gaps (not visible in this cross-section) are introduced in the RESURF region 110 along the Z-direction (width of the semiconductor device 100), allowing vertical current flow and preserving dual-channel conduction. This semiconductor structure thus supports both avalanche breakdown management and dual conduction paths.

As depicted in FIG. 3B, the RESURF region 110 extends through the drift layer 106 from the body region 108 beneath the first gate electrode 224 and the second gate electrode 222, but does not fully extend beneath the drain region 118. This configuration together with gaps (not shown) in the RESURF region 110 along the gate-width direction (z-direction) allow current to detour below the RESURF region 110 (e.g., through a lower portion of the drift layer 106), supporting a deep detoured path or second conduction channel 352 in addition to a surface path or first conduction channel 350. The thick-oxide portion of the gate insulating film 124 may extend toward the drain region 118 for electric field relief.

Accordingly, as depicted in FIG. 3B, two current paths are available between the source region 116 and the drain region 118: (i) a first surface current path (first conduction channel 350) that traverses the drift layer 106 along the surface of the body region 108and is controlled by the first gate electrode 224 and the second gate electrode 222 and (ii) a second deep current path (second conduction channel 352) that detours below the RESURF region 110 within a deeper portion of the drift layer 106 while remaining adjacent to the body region 108 and is controlled by the third gate electrode 226 positioned adjacent to the body region 108 via a corresponding portion of the gate insulating film 124.

The proposed switching scheme is designed such that the third gate electrode 226 (hard-switch gate) is activated first to allow full conduction and manage higher current levels, particularly under hard-switching or avalanche conditions with a high drain voltage. Once the drain voltage starts to drop, then the first gate electrode 224 (soft switch gate) is activated so that the hot carrier stress on this gate is lower. Stated differently, the third gate electrode 226 (hard-switch gate) is configured to be activated prior to the first gate electrode 224 (soft switch gate) and the second gate electrode 222 (rear gate or auxiliary gate) to enable primary conduction and withstand switching transients, the first gate electrode 224 is configured to be activated after the third gate electrode 226 to reduce switching stress, and the second gate electrode 222 (auxiliary gate) is configured to assist conduction and maintain switching efficiency.

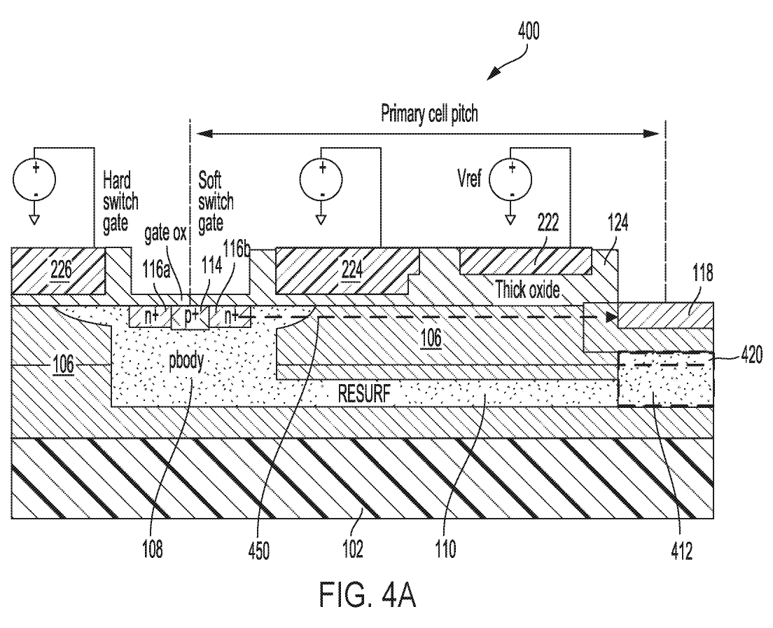

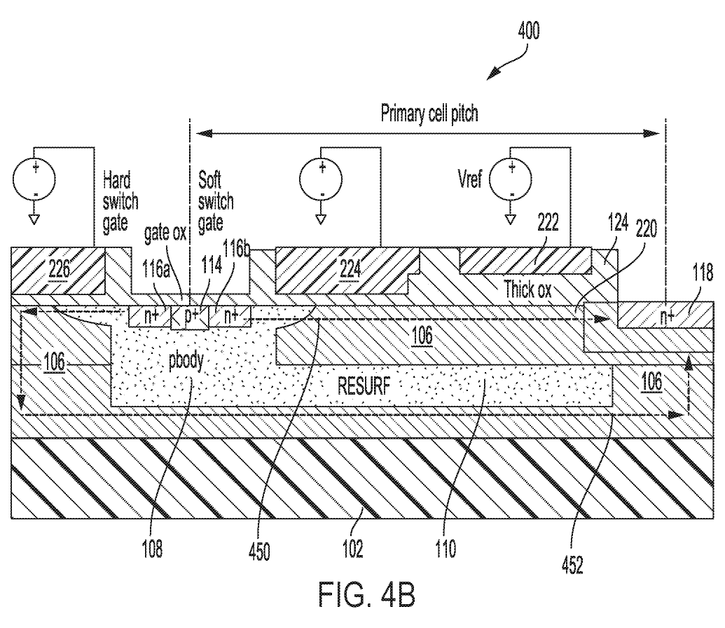

Referring now to FIGS. 4A-4B, cross-sectional views of a semiconductor device 400 illustrating an alternate multi-gate structure are shown, according to an embodiment of the present disclosure. FIG. 4A illustrates a dual-gate configuration in which the RESURF region 110 is laterally continuous across a width of the semiconductor device 400 and includes a plurality of extension regions (hereinafter “extension regions”) 112 below the drain region 118. FIG. 4B illustrates a complementary cross-section of the dual-gate configuration of FIG. 4A taken along a gate-width (z) direction through a gap of the RESURF region 110 in which the RESURF region 110 partially extends across a device width (i.e., includes laterally spaced gaps), thereby providing an alternating pattern without extension regions 112.

For ease of description, elements that are identical or functionally analogous to those previously described with reference to FIGS. 1A-3B are denoted by the same reference numerals in FIGS. 4A-4B. Unless otherwise noted, such elements have substantially the same structure and operation as previously described, and repeated description is omitted.

In this embodiment, the RESURF region 110 of the second conductivity type is positioned in the drift layer 106 and extends from the body region 108 to beneath both the first gate electrode 224 and second gate electrode 222, and further beneath the drain region 118 to shape the surface field near the drain. A portion of the RESURF region 110 underlying the drain region 118 includes the extension region(s) 412. Similar to the configuration of FIG. 1C, the extension regions 412 may be spaced apart in a direction orthogonal to the source-drain current path (gate-width direction), each extension region 412 includes a protruded portion 420 directed toward the drain region 118. The configuration of the extension regions 412 and protruded portions 420 is similar to the arrangement depicted in FIGS. 1A-1C, with the difference that, in the present embodiment, the semiconductor device 400 implements a multi-gate structure.

Across the device width, areas containing the extension regions 412 and areas without the extension regions 412 are arranged in an alternating pattern, distributing avalanche current laterally while limiting parasitic capacitance. A thick-oxide portion of the gate insulating film 124 may extend toward the drain region 118 for additional electric field relief.

As in the previous multi-gate embodiments, two conduction paths are available between the source region 116 and the drain region 118: (i) a first (surface) current path 450 that traverses the drift layer 106 along the surface of the body region 108 and is controlled by the first gate electrode 224 and the second gate electrode 222, and (ii) a second (deep) current path 452 that detours below the RESURF region 110 through a deeper portion of the drift layer 106 while remaining adjacent to the body region 108 and is controlled by the third gate electrode 226 positioned adjacent to the body region 108. These paths represent segments of the same conduction stream under different field conditions. In stress-aware operation, the third gate electrode 226 is activated first to establish the deep detoured path (452). Thereafter, the first gate electrode 224 and the second gate electrode 222 are activated to form the surface path (450) and manage switching stress.

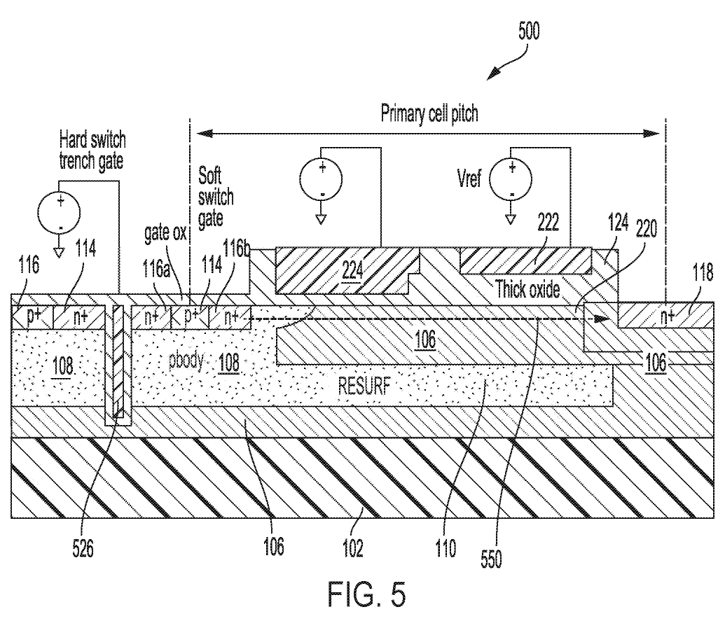

Referring now to FIG. 5, a cross-sectional view of a semiconductor device 500 illustrating a multi-gate cell in which the third gate electrode is implemented as a trench gate 526 is shown, according to an embodiment of the present disclosure. Elements common to previous embodiments use the same numerals and their repeated description is omitted.

In the depicted embodiment, the trench gate 526 is formed adjacent to the source region 116 and extending through the body region 108 and into the drift layer 106. The process of forming the trench gate 526 may include, for example, forming a trench within the body region 108 and drift layer 106, lining the trench with a liner oxide having a thickness similar to the (thin) gate insulating film 124 located below the first gate electrode 224 and then filling the trench with a gate electrode material such as polysilicon or metal. In this instance, the trench gate 526 substitutes the third gate electrode 226 depicted in previous embodiments.

In some implementations, the trench gate 526 may control a deep, detoured current path (not shown) by conducting through a lower portion of the drift layer 106 before rising toward the drain region 118, while the surface-path gate(s) (e.g., soft-switch gate or first gate electrode 224) control a surface current path 550 that runs along the surface of the body region 108, similar to previously described embodiments. In stress-aware operation, the trench gate 526 is activated first to establish the deep path under a benign electric field, followed by activation of the surface-path gate(s) to achieve low on-resistance. Implementation of the trench gate 526 enables finer cell pitch and reduced RA by improving current spreading near the rear gate region and can be combined with the RESURF layouts of the preceding embodiments (with or without staggered openings) without altering the basic operation described above.

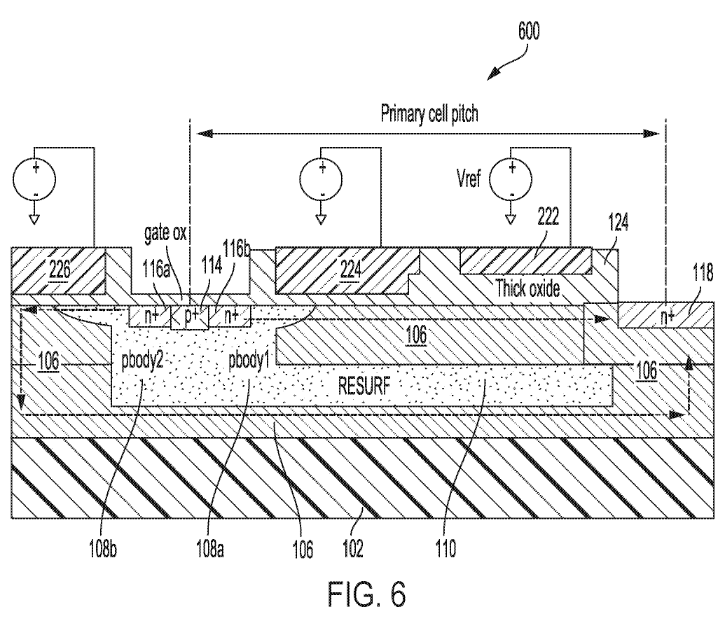

Referring now to FIG. 6, a cross-sectional view of a semiconductor device 600 illustrating a dual-gate configuration with two distinct P-type body regions is shown, according to an embodiment of the present disclosure.

In the depicted embodiment, the body region 108 is partitioned laterally into a first (P-type) body region 108a (pbody1) located beneath the first gate electrode 224 and a second (P-type) body region 108b (pbody2) located beneath/adjacent to the third gate electrode 226. N+ source diffusions 116a, 116b abut a contact region 114 in the body region 108, and the drain region 118 is provided on the opposite side, as described in previous embodiments.

In this implementation, the first body region 108a is configured with a higher threshold voltage (V_th) suitable for operation with a 1.2 V / 3.3 V / 5 V gate drive under the first gate electrode 224 (soft-switch gate), while the second body region 108b is configured with a lower V_th compatible with a 0.8 V / 1.2 V drive under the third gate electrode 226 (hard-switch gate). During reverse-recovery events, the lower-V_th region under the third gate electrode 626 turns on readily to provide an efficient lateral path (detoured below the higher-V_th region when applicable), thereby reducing reverse-recovery charge (Q_rr) and associated switching losses. In normal switching, the first gate electrode 224, second gate electrode 222, and third gate electrode 226 may be sequenced as described for earlier embodiments (e.g., rear/hard gate first, then the surface path gate) to manage stress while maintaining low on-resistance once both paths are established.

Alternative implementations may combine the dual-body scheme with the RESURF layouts previously disclosed (e.g., laterally continuous or staggered RESURF with gaps along the gate-width direction) to balance avalanche ruggedness and capacitance. In some embodiments, the impurity concentration of the first body region 108a is higher than that of the second body region 108b (supporting the different V_th targets), and the specific voltages, dimensions, and concentrations may be selected to meet the desired voltage class and performance objectives.

In certain implementations, optimized circuit designs may be used to enable or enhance the operation of the semiconductor structures described herein. These circuits may include timing, control, or driver circuitry configured to implement the proposed gate switching schemes and ensure reliable performance under various operating conditions. While specific circuit diagrams are not shown, it is understood that such circuit implementations can be tailored to support the disclosed device architectures.

### Examples

Example 1. A semiconductor device comprising:
a gate electrode positioned on a semiconductor substrate via a gate insulating film;
a drift layer of a first conductivity type located on the semiconductor substrate and extending from one end side of the gate electrode in a gate length direction;
a drain region of the first conductivity type positioned at an extended end of the drift layer;
a P-type body region of a second conductivity type opposite to the first conductivity type positioned on the semiconductor substrate on another end side of the gate electrode in the gate length direction;
a source region of the first conductivity type positioned on the semiconductor substrate on the P-type body region; and
a reduced surface field (RESURF) region of the second conductivity type in contact with a bottom of the drift layer and the P-type body region, wherein below the drain region, the reduced surface field region has a plurality of extension regions with a protruded portion extending into the drain region.

Example 2. The semiconductor device according to Example 1, wherein

areas in which the plurality of extension regions are located and areas in which the plurality of extension regions are absent are arranged alternately in a gate width direction intersecting in the gate length direction.

Example 3. The semiconductor device according to Example 2, wherein

a width of the areas in which the plurality of extension regions are located in the gate width direction is 0.2 μm or more and 5 μm or less , and

a width of the areas in which the plurality of extension regions are absent in the gate width direction is 0.2 μm or more and 5 μm or less.

Example 4. The semiconductor device according to Example 2, wherein

an extension length of the areas in which the plurality of extension regions are located in in the gate length direction is 0.2 μm or more and 2 μm or less.

Example 5. The semiconductor device according to Example 1, wherein

below the drain region, the plurality of extension regions are arranged in a comb-like shape.

Example 6. The semiconductor device according to Example 1, wherein

a height of the protruded portion from the bottom of the drift layer is 200 nm or more and 500 nm or less.

Example 7 . The semiconductor device according to Example 1, wherein

a distance from a top of the protruded portion of the plurality of extension regions to a bottom of the drain region is 200 nm or more and 1000 nm or less.

Example 8. The semiconductor device according to Example 1, wherein

the drift layer extends between the protruded portion and the drain region.

Example 9. The semiconductor device according to Example 1, wherein

the P-type body region surrounds the source region and partially overlaps with the gate electrode.

Example 10. The semiconductor device according to Example 1, wherein

the gate insulating film has a thick film portion, and

the thick film portion is extended to the drain region along with the drift layer.

Example 13. A semiconductor device comprising:
a drift layer of a first conductivity type disposed on a semiconductor substrate;
a first gate electrode positioned on the drift layer via a first gate insulating film;
a second gate electrode positioned adjacent to the first gate electrode on the drift layer via a second gate insulating film;
a drain region of the first conductivity type disposed in the drift layer on a side of the second gate electrode opposite the first gate electrode;
a P-type body region of a second conductivity type, opposite to the first conductivity type, positioned in the drift layer on a side of the first gate electrode opposite the second gate electrode;
a source region of the first conductivity type positioned in the P-type body region; and
a third gate electrode positioned on the drift layer adjacent to the P-type body region via a third gate insulating film, a first current path extending from the source to the drain through the drift layer along a surface of the P-type body region.
a second current path extending from the source to the drain through the drift layer by detouring below a region of the drift layer beneath the P-type body region, wherein the first gate electrode and second gate electrode control a current flow through the first current path, the third gate electrode controls a current flow through the second current path, and the first gate and the second gate are activated after the third gate is activated.

Example 14. The semiconductor device according to Example 13, wherein

the first gate and the second gate are simultaneously activated.

Example 15. The semiconductor device according to Example 13, wherein

the second gate insulating film is thicker than the first gate insulating film and the third gate insulating film.

Example 16. The semiconductor device according to Example 13, wherein

the drift layer is a laminate layer including a first drift layer and a second drift layer which are laminated in that order, and

the P-type body region is located on the second drift layer and partially expanding to the first drift layer.

Example 17. The semiconductor device according to Example 16, wherein

the first drift layer is electrically connected to the drain region via second drift layer, and electrically connected to the source region via second drift layer and the P-type body region.

Example 18. The semiconductor device according to Example 16, wherein

a first current flowing through a second drift layer between the source region and the drain region is controlled by a first MOSFET including the first gate electrode and the first gate insulating film, and a second MOSFET including the second gate electrode and the second gate insulating film; and

a second current, detoured below the P-type body region through a first drift layer between the source region and the drain region, is controlled by the third gate electrode and the third gate insulating film.

Example 19. The semiconductor device according to Example 15, further comprising:
a reduced surface field (RESURF) region of the second conductivity type positioned in an upper portion of the first drift layer extending from the P-type body region to a region below the first gate electrode and the second gate electrode.

Example 20. The semiconductor device according to Example 19, wherein

a first current flowing through the second drift layer between the source region and the drain region is controlled by the first MOSFET including the first gate electrode and the first gate insulating film, and the second gate electrode and the second gate insulating film; and

a second current, detoured below the reduced surface field region through the first drift layer between the source region and the drain region, is controlled by third gate electrode and the third gate insulating film.

Example 21. A semiconductor device comprising:
a drift layer of a first conductivity type disposed on a semiconductor substrate;
a first gate electrode positioned on the drift layer via a first gate insulating film;
a second gate electrode positioned on the drift layer adjacent to the first gate electrode via a second gate insulating film;
a drain region of the first conductivity type located in the drift layer on a side of the second gate electrode opposite the first gate electrode;
a P-type body region of a second conductivity type, opposite to the first conductivity type, located in the drift layer on a side of the first gate electrode opposite the second gate electrode;
a source region of the first conductivity type located in the P-type body region;
a third gate electrode positioned on the drift layer adjacent to the P-type body region via a third gate insulating film; and
a reduced surface field (RESURF) region of the second conductivity type positioned in the drift layer and extending from the P-type body region to beneath the first gate electrode and the second gate electrode, wherein:
a portion of the RESURF region underlying the drain region includes a plurality of extension regions spaced apart in a direction orthogonal to a source-to-drain current path, a first current path extending from the source to the drain through the drift layer along a surface of the P-type body region.
a second current path extending from the source to the drain through the drift layer by detouring below a region of the drift layer beneath the P-type body region, wherein the first gate electrode and second gate electrode control a current flow through the first current path, the third gate electrode controls a current flow through the second current path.
the first gate and the second gate are activated after the third gate is activated.

Example 22. The semiconductor device according to Example 21, wherein

the first gate and the second gate are simultaneously activated.

Example 23. The semiconductor device according to Example 21, wherein

areas in which the plurality of extension regions are located and areas in which the plurality of extension regions are absent are arranged in an alternating pattern.

Example 24. The semiconductor device according to Example 21, wherein

the second gate insulating film is thicker than the first gate insulating film and the third gate insulating film.

Example 25. The semiconductor device according to Example 21, wherein

a plurality of extension regions includes protruded portions extending toward the drain region.

Example 26. The semiconductor device according to Example 21, further comprising:
a trench positioned adjacent to the source region, wherein the trench extends through the P-type body region and into the drift layer, and the third gate electrode is positioned within the trench via a third gate insulating film.

Example 27. The semiconductor device according to Example 21, wherein

the P-type body region includes a first P-type body region located near the first gate electrode and a second P-type body region located near the third gate electrode, and

an impurity concentration of the first P-type body region is higher than an impurity concentration of the second P-type body region.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Spatially relative terms, such as “inner,” “outer,” “beneath,” “below,” “lower,” “above,” “upper,” “top,” “bottom,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” may encompass both an orientation of above and below. The device may be otherwise oriented (rotated 90 degrees or at other orientations) and the spatially relative descriptors used herein interpreted accordingly.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a gate electrode positioned on a semiconductor substrate via a gate insulating film;
a drift layer of a first conductivity type located on the semiconductor substrate and extending from one end side of the gate electrode in a gate length direction;
a drain region of the first conductivity type positioned at an extended end of the drift layer;
a P-type body region of a second conductivity type opposite to the first conductivity type positioned on the semiconductor substrate on another end side of the gate electrode in the gate length direction;
a source region of the first conductivity type positioned on the semiconductor substrate on the P-type body region; and
a reduced surface field (RESURF) region of the second conductivity type in contact with a bottom of the drift layer and the P-type body region,
wherein below the drain region, the reduced surface field region has a plurality of extension regions with a protruded portion extending into the drain region.

2. The semiconductor device according to claim 1,
wherein areas in which the plurality of extension regions are located and areas in which the plurality of extension regions are absent are arranged alternately in a gate width direction intersecting in the gate length direction.

3. The semiconductor device according to claim 2, wherein:
a width of the areas in which the plurality of extension regions are located in the gate width direction is 0.2 μm or more and 5 μm or less; and
a width of the areas in which the plurality of extension regions are absent in the gate width direction is 0.2 μm or more and 5 μm or less.

4. The semiconductor device according to claim 2,
wherein an extension length of the areas in which the plurality of extension regions are located in in the gate length direction is 0.2 μm or more and 2 μm or less.

5. The semiconductor device according to claim 1,
wherein below the drain region, the plurality of extension regions are arranged in a comb-like shape.

6. The semiconductor device according to claim 1,
wherein a height of the protruded portion from the bottom of the drift layer is 200 nm or more and 500 nm or less.

7. The semiconductor device according to claim 1,
wherein a distance from a top of the protruded portion of the plurality of extension regions to a bottom of the drain region is 200 nm or more and 1000 nm or less.

8. The semiconductor device according to claim 1,
wherein the drift layer extends between the protruded portion and the drain region.

9. The semiconductor device according to claim 1,
wherein the P-type body region surrounds the source region and partially overlaps with the gate electrode.

10. The semiconductor device according to claim 1, wherein:
the gate insulating film has a thick film portion; and
the thick film portion is extended to the drain region along with the drift layer.

11. A semiconductor device comprising:
a drift layer of a first conductivity type disposed on a semiconductor substrate;
a first gate electrode positioned on the drift layer via a first gate insulating film;
a second gate electrode positioned adjacent to the first gate electrode on the drift layer via a second gate insulating film;
a drain region of the first conductivity type disposed in the drift layer on a side of the second gate electrode opposite the first gate electrode;
a P-type body region of a second conductivity type, opposite to the first conductivity type, positioned in the drift layer on a side of the first gate electrode opposite the second gate electrode;
a source region of the first conductivity type positioned in the P-type body region;
a third gate electrode positioned on the drift layer adjacent to the P-type body region via a third gate insulating film,
a first current path extending from the source region to the drain region through the drift layer along a surface of the P-type body region; and
a second current path extending from the source region to the drain region through the drift layer by detouring below a region of the drift layer beneath the P-type body region,
wherein:
the first gate electrode and second gate electrode control a current flow through the first current path;
the third gate electrode controls a current flow through the second current path; and
the first gate electrode and the second gate electrode are activated after the third gate electrode is activated.

12. The semiconductor device according to claim 11,
wherein the first gate electrode and the second gate electrode are simultaneously activated.

13. The semiconductor device according to claim 11,
wherein the second gate insulating film is thicker than the first gate insulating film and the third gate insulating film.

14. The semiconductor device according to claim 11, wherein:
the drift layer is a laminate layer including a first drift layer and a second drift layer which are laminated in that order; and
the P-type body region is located on the second drift layer and partially expanding to the first drift layer.

15. The semiconductor device according to claim 14,
wherein the first drift layer is electrically connected to the drain region via the second drift layer, and electrically connected to the source region via the second drift layer and the P-type body region.

16. The semiconductor device according to claim 14, wherein:
a first current flowing through a second drift layer between the source region and the drain region is controlled by a first MOSFET including the first gate electrode and the first gate insulating film, and the second gate electrode and the second gate insulating film; and
a second current, detoured below the P-type body region through a first drift layer between the source region and the drain region, is controlled by a second MOSFET including the third gate electrode and the third gate insulating film.

17. The semiconductor device according to claim 16, further comprising:
a reduced surface field (RESURF) region of the second conductivity type positioned in an upper portion of the first drift layer extending from the P-type body region to a region below the first gate electrode and the second gate electrode.

18. The semiconductor device according to claim 17, wherein:
a first current flowing through the second drift layer between the source region and the drain region is controlled by the first MOSFET including the first gate electrode and the first gate insulating film, and the second gate electrode and the second gate insulating film; and
a second current, detoured below the reduced surface field region through the first drift layer between the source region and the drain region, is controlled by the third gate electrode and the third gate insulating film.
